(19) United States
(12) Patent Application Publication
(10) Pub. No.: US 2023/0089019 A1
(43) Pub. Date: Mar. 23, 2023

(54) MAGNETIC PART USING WINDING COIL AND PATTERN COIL

(71) Applicant: LG INNOTEK CO., LTD., Seoul (KR)

(72) Inventors: Kwang Soon JUNG, Seoul (KR); Jeong Heum PARK, Seoul (KR)

(21) Appl. No.: 17/908,114

(22) PCT Filed: Mar. 8, 2021
(86) PCT No.: PCT/KR2021/002800

§ 371 Date: Aug. 30, 2022

(30) Foreign Application Priority Data
Mar. 6, 2020 (KR) 10-2020-0028178

(51) Int. Cl. H01F 27/28; H05K 1/16; H01F 27/24

(52) U.S. Cl. CPC H01F 27/2804; H05K 1/165; H01F 27/24; H05K 2201/10272

(57) ABSTRACT

A magnetic part according to an embodiment of the present invention comprises: a printed circuit board; a pattern coil formed on at least a surface of the printed circuit board; a core passing through the printed circuit board; and at least one winding coil disposed on at least a surface from among one surface and the other surface of the printed circuit board.

### DESCRIPTION OF INVENTION

### Technical Field

The present invention relates to a magnetic component, and more particularly, relates to a magnetic component using a winding coil and a pattern coil, and a transformer including the same.

### Background Art

Recently, as a high power density is required for a switching mode power supply (SMPS), research for miniaturizing a transformer that occupies a large volume in the SMPS is being conducted. Among them, there is a method of lowering the height of the transformer by using a planar magnetic component. In manufacturing a planar transformer, a multilayer PCB may be required to ensure a sufficient number of windings and pattern areas. However, the use of multilayer PCBs becomes a factor that increases the cost.

### DETAILED DESCRIPTION OF THE INVENTION

### Technical Subject

A technical problem to be solved by the present invention is to provide a magnetic component using a winding coil and a pattern coil, and a transformer or an inductor including the same.

The problems of the present invention are not limited to the problems mentioned above, and other problems not mentioned will be clearly understood by those skilled in the art from the following description.

### Technical Solution

In order to solve the above technical problem, a magnetic component according to an embodiment of the present invention comprises: a printed circuit board; a pattern coil formed on at least one surface of the printed circuit board; a core penetrating the printed circuit board; and at least one or more winding coils being disposed on at least one surface of one surface and the other surface of the printed circuit board.

In addition, the printed circuit board may include at least one through hole into which a part of the core is inserted.

In addition, the printed circuit board may include: a first hole into which a part of the core is inserted; and at least one second hole into which the other part of the core is inserted.

In addition, one of the pattern coil and the winding coil may be a primary coil, and the other one may be a secondary coil.

In addition, the winding coil is configured in plurality, and at least two winding coils among the plurality of winding coils may be connected in series, parallel, or series-parallel.

In addition, the winding coil may be configured in plurality, and at least two winding coils among the plurality of winding coils may be coils of different orders.

In addition, at least one winding coil among the plurality of winding coils may be disposed on one surface of the printed circuit board, and the other winding coil may be disposed on the other surface of the printed circuit board.

In addition, the core may include: a first core being disposed on one surface of the printed circuit board; and a second core being disposed on the other surface of the printed circuit board, wherein the first core and the second core may include a central core penetrating the first hole of the printed circuit board.

In addition, it may include a coupling part for coupling the first core and the second core.

In order to solve the above technical problem, a transformer according to an embodiment of the present invention comprises: a printed circuit board; a pattern coil being formed on one surface of the printed circuit board; a core penetrating the printed circuit board; and at least one or more winding coils being disposed on at least one surface of one surface and the other surface of the printed circuit board and being formed around the core, wherein one of the pattern coil and the winding coil is a primary coil and the other one is a secondary coil.

### Advantageous Effects

According to embodiments of the present invention, it is possible to reinforce the insufficient number of turns and patterns only with the pattern coil formed on the printed circuit board. In addition, it is easy to obtain the desired effect according to the type of winding coil used. By using a winding coil, it is possible to reduce the number of layers of the printed circuit board required, thereby possibly lowering the printed circuit board cost.

The effect according to the invention is not limited by the contents exemplified above, and more various effects are included in the present specification.

### BRIEF DESCRIPTION OF DRAWINGS

FIG. 1 illustrates a magnetic component according to an embodiment of the present invention.

FIG. 2 is an exploded perspective view of a magnetic component according to an embodiment of the present invention.

FIGS. 3 to 9 illustrate a magnetic component according to another embodiment of the present invention.

### BEST MODE

Hereinafter, preferred embodiments of the present invention will be described in detail with reference to the accompanying drawings.

However, the technical idea of the present invention is not limited to some embodiments to be described, but may be implemented in various forms, and within the scope of the technical idea of the present invention, one or more of the constituent elements may be selectively combined or substituted between embodiments.

In addition, the terms (including technical and scientific terms) used in the embodiments of the present invention, unless explicitly defined and described, can be interpreted as a meaning that can be generally understood by a person skilled in the art, and commonly used terms such as terms defined in the dictionary may be interpreted in consideration of the meaning of the context of the related technology.

In addition, terms used in the present specification are for describing embodiments and are not intended to limit the present invention.

In the present specification, the singular form may include the plural form unless specifically stated in the phrase, and when described as “at least one (or more than one) of A and B and C”, it may include one or more of all combinations that can be combined with A, B, and C.

In addition, in describing the components of the embodiment of the present invention, terms such as first, second, A, B, (a), and (b) may be used. These terms are merely intended to distinguish the components from other components, and the terms do not limit the nature, order or sequence of the components.

And, when a component is described as being ‘connected’, ‘coupled’ or ‘interconnected’ to another component, the component is not only directly connected, coupled or interconnected to the other component, but may also include cases of being ‘connected’, ‘coupled’, or ‘interconnected’ due that another component between that other components.

In addition, when described as being formed or arranged in “on (above)” or “below (under)” of each component, “on (above)” or “below (under)” means that it includes not only the case where the two components are directly in contact with, but also the case where one or more other components are formed or arranged between the two components. In addition, when expressed as “on (above)” or “below (under)”, the meaning of not only an upward direction but also a downward direction based on one component may be included.

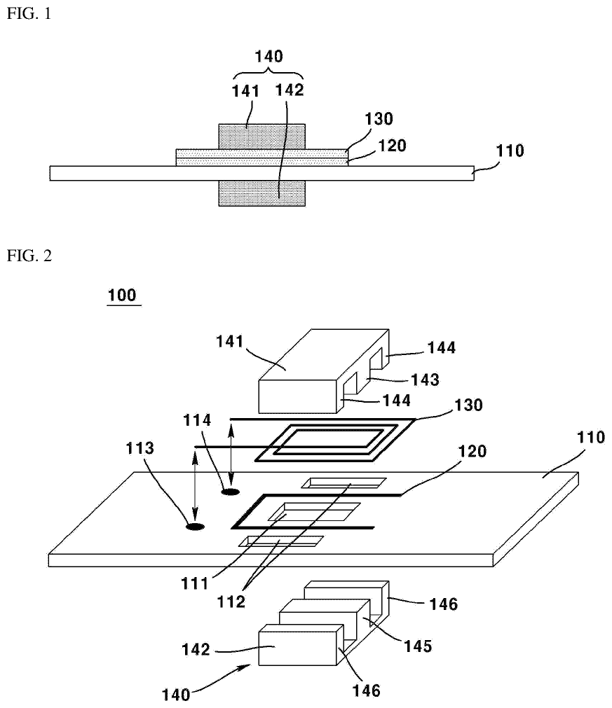

FIG. 1 illustrates a magnetic component according to an embodiment of the present invention; and FIG. 2 is an exploded perspective view of a magnetic component according to an embodiment of the present invention.

The magnetic component according to an embodiment of the present invention means a part in which a current is applied to a coil to form magnetism, and comprises a printed circuit board 110, a pattern coil 120 formed on one surface of the printed circuit board 110, a core 140, and a winding coil 130. The magnetic component according to an embodiment of the present invention may be various magnetic components such as a transformer, an inductor, or a converter including a transformer.

The printed circuit board 110 is a printed circuit board (PCB) board, and may be formed in a plate shape, and is formed by printing a pattern coil 120 on at least one of an upper surface and a lower surface of the printed circuit board 110. In addition to the pattern coil 120, various electronic components for driving may be disposed.

The pattern coil 120 may be formed by printing on the printed circuit board 110 in the form of a coil. The pattern coil 120 may be formed in a bent shape on the printed circuit board 110 as shown in FIG. 2. As shown in FIG. 2, it may be formed in a bent shape, or may be formed in the shape of a circle, an ellipse, or a spiral, and may be formed in various shapes. Both ends of the pattern coil 120 may be connected to a feed line portion or a ground portion of the printed circuit board 110.

The pattern coil 120 may be formed of a metal pattern. The pattern coil 120 may be formed by printing a metal pattern on the printed circuit board 110. The metal pattern may be in the form of a thin film having a predetermined height. Here, the metal pattern may include a copper foil of 0.5 to 2 oz. In addition, it may be formed of various heights and materials.

The pattern coil 120 may be formed on one surface or both surfaces of the printed circuit board 110. When formed on both surfaces, the pattern coils 120 on both surfaces may be connected to each other or insulated without being connected to each other depending on the number of required orders or the shape of the pattern coil 120 to be formed. When the pattern coils 120 on both surfaces are connected to each other, via holes may be formed in the printed circuit board 110 to be connected to each other.

A plurality of pattern coils 120 may be formed on one surface of the printed circuit board 110. When a plurality of pattern coils 120 are formed on the same surface of the printed circuit board 110 and are to be insulated without being connected to each other, they may be formed to be spaced apart from each other at an interval enabling insulation so as to be insulated. The pattern coil 120 is formed on one surface or both surfaces of the printed circuit board 110 or a plurality of pattern coils 120 are formed on one printed circuit board 110, thereby possibly forming the pattern coils 120 in various forms by being printed on the printed circuit board 110.

The core 140 is formed to penetrate the printed circuit board 110. The core 140 is a central structure surrounded by the pattern coil 120 or the winding coil 130. The core 140 is formed by penetrating through the printed circuit board 110, and the pattern coil 120 and the winding coil 130 may be formed to surround the core 140 as a center. The core 140 may be formed of a material having a ferrite structure. It is natural that it may be formed of other materials.

The core 140 may include central cores 143 and 145 penetrating the printed circuit board 110 as shown in FIG. 2, and may be further include side cores 144 and 146 formed on both sides of the central cores 143 and 145. The central cores 143 and 145 are central structures being surrounded by the pattern coil 120 or the winding coil 130, and the side cores 144 and 146 may be the structures to maintain the shape of the core 140. Both the central cores 143 and 146 and the side cores 144 and 146 may be formed to penetrate the printed circuit board 110. Or, only the central cores 143 and 145 may penetrate through the printed circuit board 110, and the side cores 144 and 146 may be formed to be extended to the side surface that does not penetrating through the printed circuit board 110 so as to be passed by. At this time, the length of the core 140 in a direction in which the side cores 144 and 146 are formed may be longer than the length in the corresponding direction of the printed circuit board 110. FIG. 2 is illustrated as one of the central cores 143 and 145 and two side cores 144 and 146, but it is natural that the number of cores being extended from one core may be more than that or may be formed in various shapes, as if a plurality of cores is formed instead of one core.

The core 140 may include a first core 141 being disposed on one surface of the printed circuit board 110 and a second core 142 being disposed on the other surface of the printed circuit board 110. The core 140 being formed of two cores is disposed at both sides of the printed circuit board 110, and the cores penetrate through the printed circuit board 110 to be coupled to each other. To this end, the first core 141 and the second core 142 may be formed in the shape corresponding to each other. The first core 141 is formed of a central core 143 and two side cores 144, and the second core 142 is formed of a central core 145 and two side cores 146 corresponding thereto. Corresponding cores may be connected to each other by penetrating through the printed circuit board 110. Or, the first core 141 is formed of the central core 143 and the side core 144, and the second core 142 is formed only in a plate shape without the central core 145 and the side core 146, or the region of the second core 142 corresponding to the side core 144 may be formed in a concave shape so that the first core 141 can be fit-coupled thereto. In addition, it is natural that it may be formed in various forms.

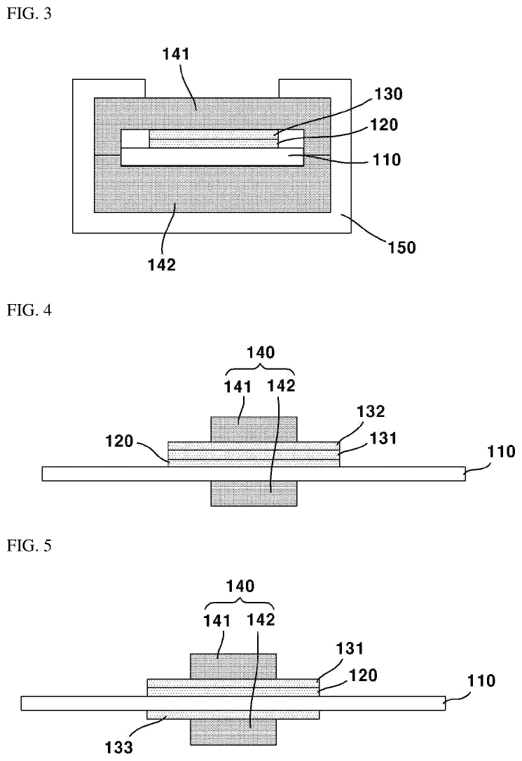

When the core 140 includes the first core 141 and the second core 142, the first core 141 and the second core 142 are coupled through an adhesive, or may be coupled through a coupling part 150 coupling the first core 141 and the second core 142. FIG. 3 is a magnetic component according to a second embodiment of the present invention, and illustrates a form in which a coupling part 150 for coupling the first core 141 and the second core 142 is formed. As a view viewed from a direction different from the direction shown in FIG. 1, the core 140 is formed of a first core 141 and a second core 142, and each core is formed of a central core and a side core, wherein the side core does not penetrate the printed circuit board, but is extended to the side surface of the printed circuit board to be connected to each other. The coupling part 150 may be formed to surround the first core 141 and the second core 142 so that the first core 141 and the second core 142 can maintain the state of being connected. The coupling part 150 may be an elastic clip. The connection state of the first core 141 and the second core 142 may be maintained by fit-coupling of the first core 141 and the second core 142 together with the coupling part 150 in a state in which they are connected to each other. In addition, it is natural that the first core 141 and the second core 142 may be connected and fixed to each other in various ways and shapes. For example, when the first core 141 and the second core 142 are coupled while penetrating the printed circuit board 110, the first core 141 and the second core 142 may be coupled by letting the coupling part 150 simultaneously penetrate the through hole of the printed circuit board 110 through which the side core 144 of the first core 141 and the side core 146 of the second core 142 penetrate. Or, the first core 141 and the second core 142 may be coupled by arranging the coupling part 150 to surround the side surface of the printed circuit board 110 when the first core 141 and the second core 142 are coupled while penetrating the printed circuit board 110.

The printed circuit board 110 may include at least one of through holes 111 and 112 into which a part of the core 140 is inserted. The through holes 111 and 112 may be formed in the printed circuit board 110 so that the core 140 may be inserted therethrough. The through holes 111 and 112 being formed in the printed circuit board 110 may be formed according to the shape of the core 140.

The printed circuit board 110 may include a first hole 111 into which a part of the core is inserted and at least one second hole 112 into which the other part of the core is inserted, depending on the shape of the core 140. As described above, as in FIG. 2, when one of the central cores 143 and 145 and two side cores 144 and 146 are formed to penetrate through the printed circuit board 110, in response to this, a first hole 111 through which the central cores 143 and 145, which is a part of the core, penetrates and two second holes 112 through which the side cores 144 and 146, which is the other part of the core, penetrate may be formed. When only the central cores 143 and 145 penetrate the printed circuit board 110, and the two side cores 144 and 146 are extended laterally without penetration, only the first hole 111, which is one through hole, may be formed.

At least one winding coil 130 may be formed to be disposed on at least one surface of one surface and the other surface of the printed circuit board 110. The winding coil 130 is a coil wound with a wire, and may be formed on at least one surface of one surface or the other surface of the printed circuit board 110. The winding coil 130 is formed by bending a wire, and as shown in FIG. 2, both ends may be connected to a feed line portion or a ground portion of the printed circuit board 110 through soldering or the like.

The winding coil 130 may be formed of a coil in a bent form, as shown in FIG. 2, or may be formed in various forms such as a circle, an ellipse, or a spiral. The winding coil 130 may be formed in a shape surrounding the core 140, and the number of windings may vary according to the turn ratio.

The winding coil 130 is formed on one surface of the printed circuit board 110 on which the pattern coil 120 is printed, or may be formed on the other surface of the printed circuit board 110 on which the pattern coil 120 is not printed, as shown in FIG. 2. When the pattern coil 120 is formed on a non-printed surface, it may be easy to insulate from the pattern coil 120.

The winding coil 130 may be disposed between the first hole 111 and the second hole 112 when the first hole 111 and the second hole 112 are formed in the printed circuit board 110. That is, when the core 140 is formed of the central cores 143 and 145 and the side cores 144 and 146, the winding coil 130 may be formed in a shape surrounding the central cores 143 and 145, Accordingly, the winding coil 130 may be disposed between the central cores 143 and 145 and the side cores 144 and 146.

One of the pattern coil 120 and the winding coil 130 may be a primary coil, and the other may be a secondary coil. When the magnetic component 100 to be implemented includes a primary coil and a secondary coil, the pattern coil 120 may be a primary coil, the winding coil 130 may be a secondary coil, or the winding coil 130 may be a primary coil, and the pattern coil 120 may be a secondary coil. At this time, since the primary coil and the secondary coil are formed, the magnetic component 100 may implement a transformer capable of transforming according to the turns ratio of each coil. When the pattern coil 120 and the winding coil 130 are formed as a primary coil and a secondary coil, respectively, in forming the turn ratio, the pattern coil 120 may have a limit depending on the area of the printed circuit board 110. When other components other than the pattern coil 120 are further included on the printed circuit board 110, the limitation on the turn ratio of the pattern coil 120 may be increased. In order to implement a large turn ratio using the pattern coil 120, it may be difficult with one printed circuit board so a plurality of printed circuit boards may be required. In contrast, the winding coil 130 has fewer restrictions in implementing the turn ratio compared to the pattern coil 120. Therefore, it is possible to implement a wider range of turn ratio using the winding coil 130. Accordingly, by forming the winding coil 130 with a coil having a high number of turns according to the turn ratio for the transformation, the number of turns can be easily implemented.

When the pattern coil 120 and the winding coil 130 are formed of coils of different orders, they are not connected to each other and must be insulated. To this end, the pattern coil 120 and the winding coil 130 may be formed to be spaced apart from each other by a predetermined distance or more. When forming coils of different orders, they should not be electrically connected to each other, and thus may be formed to be spaced apart from each other by more than a distance for insulation.

Or, for insulation, an insulation layer disposed between the pattern coil 120 and the winding coil 130 may be included. If the gap between the pattern coil 120 and the winding coil 130 is difficult to be spaced apart enough for insulation, an insulation layer may be formed for reliable insulation, and thereby the pattern coil 120 and the winding coil 130 may be insulated.

When the pattern coil 120 and the winding coil 130 are connected to each other to form a single coil, the pattern coil 120 and the winding coil 130 may implement an inductor that forms an inductance. When the pattern coil 120 and the winding coil 130 form one coil, the number of windings that is difficult to implement only with the pattern coil 120 can be reinforced by using the winding coil 130. In the case of implementing only the pattern coil 120, when one printed circuit board 110 is insufficient and a plurality of printed circuit boards 110 are required, by reinforcing the number of windings with the winding coil 130, it is possible to reduce the number of layers of the printed circuit board 110 or to implement the number of windings to be implemented with only one printed circuit board 110.

The number of winding coils 130 is plural, and at least two winding coils of the plurality of winding coils may be connected in series, parallel, or series-parallel. The winding coil 130 may be formed of a plurality of winding coils. One winding coil means a winding coil formed by one wire, and a plurality of winding coils means that a plurality of individual winding coils is included therein.

When using multiple winding coils, multiple winding coils can be used for two different reasons. First, a plurality of winding coils may be used to reinforce the number of windings or increase the capacity of the winding coil 130. In this case, each winding coil may be connected to each other to form one winding coil. At this time, the winding coils may be connected to each other in series, parallel, or series-parallel. The winding coils may be connected in series or in parallel depending on the desired turns ratio, and in the case of three or more winding coils, they may be connected in series or parallel. When winding coils are connected in series with each other, the total number of turns becomes the sum of the number of windings connected in series, and when winding coils are connected in parallel with each other, the total number of turns may become equal to the number of turns of one winding coil. The connection type between winding coils can be formed differently depending on the number of windings and capacity to be implemented.

Or, at least two winding coils among the plurality of winding coils may form coils of different orders by using the plurality of winding coils 130. In this case, since the plurality of winding coils form coils of different orders, they may be insulated without being connected to each other. As described above, the pattern coil 120 may form a primary coil and winding coil 130 may form a secondary coil, and when implementing an nth coil, such as 3rd, 4th, and the like, each of the pattern coil 120 and the plurality of winding coils 130 may be formed as a coil of a specific order.

In forming the plurality of winding coils, some of the plural winding coils form coils of different orders, and some of the remaining ones may be connected to each other to reinforce the number of windings. Some of the plural winding coils may form a primary coil and others may form a secondary coil. At this time, the winding coil forming the primary coil and the winding coil forming the secondary coil may be alternately stacked with each other. By stacking the primary coil and the secondary coil alternately, the transformation efficiency can be increased and errors can be reduced.

In addition to the winding coil 130, the pattern coil 120 may also be formed of a plurality of pattern coils 120. The plurality of pattern coils may form coils of different orders. In this case, the pattern coil 120 may be formed by printing the first pattern coil and the second pattern coil being electrically insulated from the first pattern coil on the printed circuit board 110. The first pattern coil and the second pattern coil may not be connected to each other or, when connected to each other, may be connected in series, parallel, or series-parallel. The plurality of pattern coils 120 may be formed by printing on one printed circuit board 110, or may be formed by printing one pattern coil 120 on a plurality of printed circuit boards 110.

In the case of including a plurality of winding coils, unlike the embodiment of FIG. 1, the magnetic component may be implemented in various embodiments as shown in FIGS. 4 to 7. A detailed description of each configuration of the magnetic component of FIGS. 4 to 7 corresponds to a detailed description of each configuration of the magnetic component of FIGS. 1 to 3, and hereinafter, overlapping descriptions will be omitted.

FIG. 4 is a magnetic component according to a third embodiment of the present invention. Referring to FIG. 4, the magnetic component according to a third embodiment of the present invention may comprise a printed circuit board 110, a pattern coil 120, a plurality of windings coils 131 and 132, and a core 140.

The printed circuit board 110 is a plate shape and is formed by printing a pattern coil 120 on one surface thereof. A plurality of winding coils 131 and 132 may be formed on the surface on which the pattern coil 120 is formed. Although only two winding coils 131 and 132 are illustrated in FIG. 4, it is natural that a winding coil may be formed of three or more winding coils.

The plurality of winding coils 131 and 132 may form coils of different orders, respectively. Or, the number of windings may be reinforced by being connected to each other or connected to the pattern coil 120. When connecting between the coils, they can be connected in series, parallel or series-parallel.

FIG. 5 is a magnetic component according to a fourth embodiment of the present invention. Referring to FIG. 5, the magnetic component according to the fourth embodiment of the present invention may comprise a printed circuit board 110, a pattern coil 120, a plurality of winding coils 131 and 133, and a core 140.

The printed circuit board 110 may be a double-sided printed circuit board, or via holes may be formed in a single-sided printed circuit board so that the coils can be connected to both sides. The printed circuit board 110 is a plate shape and may have a pattern coil formed on one side or both sides. As for the two winding coils 131 and 133, one winding coil may be disposed on one surface and the other surface thereof on which the pattern coil 120 is formed, respectively.

The plurality of winding coils 131 and 133 may form coils of different orders, respectively. Or, the number of windings may be reinforced by being connected to each other or connected to the pattern coil 120. When connecting between the coils, they can be connected in series, parallel or series-parallel.

FIG. 6 is a magnetic component according to a fifth embodiment of the present invention. Referring to FIG. 6, the magnetic component according to the fifth embodiment of the present invention may comprise a printed circuit board 110, a pattern coil 120, a plurality of winding coils 131, 132, 133, and 134, and a core 140.

The printed circuit board 110 may be a double-sided printed circuit board, or via holes may be formed in the single-sided printed circuit board so that the coils can be connected to both sides. The printed circuit board 110 is a plate shape, and a pattern coil may be formed on one side or both sides thereof. In each of the four winding coils 131, 132, 133, and 134, two winding coils may be disposed respectively on one surface and the other surface thereof on which the pattern coil 120 is formed. FIG. 6 illustrates four winding coils 131, 132, 133, and 134 as being disposed respectively on both sides by two, but it is natural that six, eight or more winding coils may be included in a symmetrical number.

The plurality of winding coils 131, 132, 133, and 134 may form coils of different orders, respectively. Or, the number of windings may be reinforced by being connected to each other or connected to a pattern coil 120. When connecting between the coils, they can be connected in series, parallel or series-parallel. When the coils of different orders are formed, the coils forming the primary coil and the coils forming the secondary coil may be stacked alternately.

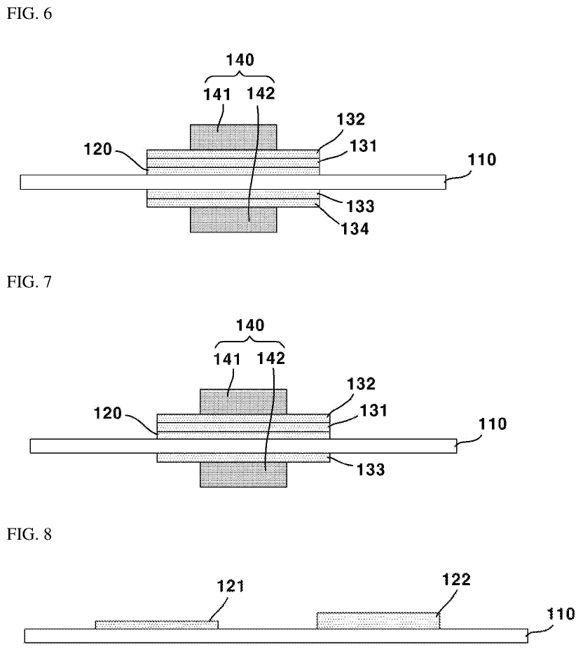

FIG. 7 is a magnetic component according to a sixth embodiment of the present invention. Referring to FIG. 7, the magnetic component according to the sixth embodiment of the present invention may comprise a printed circuit board 110, a pattern coil 120, a plurality of winding coils 131, 132, 133, and a core 140. In the case of FIGS. 5 and 6, a plurality of winding coils are formed symmetrically with each other, whereas in the magnetic component according to a sixth embodiment of FIG. 7, a plurality of winding coils may be formed asymmetrically.

The printed circuit board 110 may be a double-sided printed circuit board, or via holes may be formed in the single-sided printed circuit board so that the coils can be connected to both sides. The printed circuit board 110 is a plate shape and a pattern coil may be formed on one side or both sides thereof. In each of the three winding coils 131, 132, and 133, two winding coils 131 and 132 may be disposed on one surface on which the pattern coil 120 is formed and one winding coil 133 may be disposed on the other surface. FIG. 7 illustrates that three winding coils 131, 132, and 133 are disposed on both sides, it is natural that more winding coils may be included.

The plurality of winding coils 131, 132, and 133 may form coils of different orders, respectively. Or, the number of windings may be reinforced by being connected to each other or connected to a pattern coil 120. When connecting between the coils, they can be connected in series, parallel or series-parallel. When the coils of different orders are formed, the coils forming the primary coil and the coils forming the secondary coil may be stacked alternately.

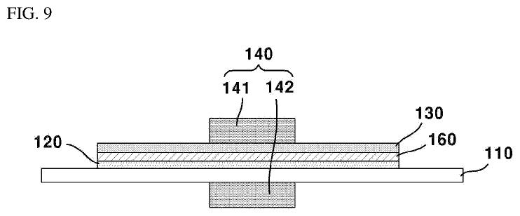

In reinforcing the pattern coil 120, as described above, the winding coil 130 may be connected, a thick metal pattern may be formed, or a bus or angular copper wire may be used. As shown in FIG. 8, when the pattern coil 120 is formed, the metal patterns 121 and 122 formed on the printed circuit board 110 may have a thickness of 0.5 to 2 oz. In order to reinforce the pattern coil 120, the thickness of the metal pattern 122 may be 2 oz or more. For example, metal patterns 121 and 122 of 2 to 5 oz may be formed. Or, all of the metal patterns 121 and 122 having different thicknesses may be used.

Or, in order to reinforce the pattern coil 120, an angled copper wire, not a metal pattern, may be used. The angled copper wire is a copper wire being angled, and is also referred to as a flat angled wire or a flat angled copper wire. The angled copper wire has a large cross-sectional area, so it is easy to conduct a large current and maintain its shape.

Or, in order to reinforce the pattern coil 120, as shown in FIG. 9, the bus bar 160 may be used. The busbar is a metal bar, and in order to conduct a large current, the pattern coil 120 may be reinforced by disposing the busbar 160 on the pattern coil 120.

The winding coil 130 may include at least one of an enameled copper wire, Litz wire, a triple insulation wire, and an angled copper wire.

Enameled copper wire is a copper wire whose surface is fusion welded with an inorganic glass material, and it has low flexibility compared to other wires, but it is easy to maintain its shape when a coil shape is formed. Therefore, there is an advantage that can be directly coupled to the printed circuit board without a separate auxiliary means for fixing the shape.

Litz wire is a wire made of 10 to tens of thin enameled copper wires (or polyurethane wires, and the like) each of them being coated with a special insulator or wrapped with silk; and it is a wire for improving frequency characteristics by physically increasing the surface area and electrically reducing the skin effect. Litz wire is excellent in reducing losses due to AC current and has high flexibility compared to other wires. However, when forming a coil shape, it is difficult to maintain the shape. Therefore, there is a need for an auxiliary means for maintaining the coil shape.

To this end, it may include a shape maintaining part for maintaining the shape of the winding coil. In the case of a wire wound coil using a wire, it may be difficult to maintain the shape of the coil formed by the wire itself depending on the material of the wire. In this case, an auxiliary means or a mechanism for maintaining the coil shape may be used.

Triple insulation wire has excellent electrical insulation compared to other wires. Therefore, it is easy to secure the insulation between the primary and the secondary when winding a transformer. Therefore, there is an advantage of being able to insulate without securing an insulation distance or auxiliary means for insulation between the primary and secondary of the transformer. In the case of transformer, the wire insulation distance between primary and secondary is standardized and managed, but when using triple insulated wire, it is possible to satisfy the specification without insulation distance. At this time, even if a triple insulated wire is applied only to one side of the primary or secondary wire, it is possible to secure the insulation between the primary and secondary wires.

As described above, an angled copper wire has a larger cross-sectional area compared to other wires, so it is easy to conduct a large current. In addition, it is easy to maintain the molded shape like an enameled copper wire coil. Therefore, there is an advantage that can be directly coupled to the printed circuit board without a separate auxiliary means for fixing the shape.

The magnetic component according to an embodiment of the present invention may implement various devices including magnetic components, such as a transformer, a converter, an inductor, and the like according to a method in which each coil is connected.

A transformer according to an embodiment of the present invention comprises one printed circuit board on which a pattern coil is printed, a core, and a winding coil, and it may be a planar transformer and may be used in a PSU for a TV or in a power supply for a battery vehicle. A detailed description of the transformer according to an embodiment of the present invention corresponds to the detailed description of the magnetic component of FIGS. 1 to 9, and overlapping descriptions thereof will be omitted.

A transformer according to an embodiment of the present invention comprises: a printed circuit board on which a pattern coil is printed on at least one surface thereof; a core penetrating the printed circuit board; and at least one or more winding coils being disposed on at least one of one surface and the other surface of the printed circuit board, and being formed around the core, wherein one of the pattern coil and the winding coil is a primary coil, and the other one forms a secondary coil.

An inductor according to an embodiment of the present invention comprises one printed circuit board, a core, and a winding coil, and it may be an inductor having a plurality of phases or having a plurality of phases being coupled with another. A detailed description of the inductor according to an embodiment of the present invention corresponds to the detailed description of the magnetic component of FIGS. 1 to 9, and overlapping descriptions thereof will be omitted.

An inductor according to an embodiment of the present invention comprises: one printed circuit board on which a pattern coil is printed on at least one surface; a core penetrating through the printed circuit board; and at least one winding coil being disposed on at least one surface of one surface and the other surface of the printed circuit board, and formed around the core, wherein the pattern coil and the winding coil are connected in series, parallel, or series-parallel.

As described above, the present invention has been described with specific matters such as specific configurational elements and limited embodiments and drawings, but these are only provided to help a more general understanding of the present invention, and the present invention is not limited to the above embodiments, and those of ordinary skill in the art to which the present invention belongs can make various modifications and variations of the position measuring unit from such a description.

Therefore, the spirit of the present invention should not be limited to the described embodiments, and not only the claims to be described later, but also all those with equivalent or equivalent modifications to the claims will be said to belong to the scope of the spirit of the present invention.

1. A magnetic component comprising:
a printed circuit board;
a pattern coil formed on at least one surface of the printed circuit board;
a core penetrating the printed circuit board; and
at least one or more winding coils disposed on at least one surface of one surface and the other surface of the printed circuit board.

2. The magnetic component according to claim 1,
wherein the printed circuit board comprises at least one through hole into which a part of the core is inserted.

3. The magnetic component according to claim 2,
wherein the printed circuit board comprises:
a first hole into which a part of the core is inserted; and
at least one second hole into which the other part of the core is inserted.

4. The magnetic component according to claim 1,
wherein one of the pattern coil and the winding coil is a primary coil, and the other one is a secondary coil.

5. The magnetic component according to claim 1,
wherein the winding coil is configured in plurality, and
wherein at least two winding coils among the plurality of winding coils are connected in series, parallel, or series-parallel.

6. The magnetic component according to claim 1,
wherein the winding coil is configured in plurality, and
wherein at least two winding coils among the plurality of winding coils are coils of different orders.

7. The magnetic component according to claim 5,
wherein at least one winding coil among the plurality of winding coils is disposed on one surface of the printed circuit board, and the other winding coil is disposed on the other surface of the printed circuit board.

8. The magnetic component according to claim 3,
wherein the core comprises:
a first core disposed on one surface of the printed circuit board; and
a second core disposed on the other surface of the printed circuit board,
wherein the first core and the second core comprise a central core penetrating the first hole of the printed circuit board.

9. The magnetic component according to claim 8, comprising:
a coupling part coupling the first core and the second core.

10. (canceled)

11. The magnetic component according to claim 1, comprising:
a bus bar disposed on the pattern coil.

12. A transformer comprising:
a printed circuit board;
a pattern coil formed on one surface of the printed circuit board;
a core penetrating the printed circuit board; and
at least one or more winding coils disposed on at least one surface of one surface and the other surface of the printed circuit board and formed around the core,
wherein one of the pattern coil and the winding coil is a primary coil and the other one is a secondary coil.

13. The transformer according to claim 12,
wherein the printed circuit board comprises at least one through hole into which a part of the core is inserted.

14. The transformer according to claim 13,
wherein the printed circuit board comprises:
a first hole into which a part of the core is inserted; and
at least one second hole into which the other part of the core is inserted.

15. The transformer according to claim 12,
wherein one of the pattern coil and the winding coil is a primary coil, and the other one is a secondary coil.

16. The transformer according to claim 12,
wherein the winding coil is configured in plurality, and
wherein at least two winding coils among the plurality of winding coils are connected in series, parallel, or series-parallel.

17. The transformer according to claim 16,
wherein at least one winding coil among the plurality of winding coils is disposed on one surface of the printed circuit board, and the other winding coil is disposed on the other surface of the printed circuit board.

18. The transformer according to claim 12,
wherein the winding coil is configured in plurality, and
wherein at least two winding coils among the plurality of winding coils are coils of different orders.

19. The transformer according to claim 14,
wherein the core comprises:
a first core disposed on one surface of the printed circuit board; and
a second core disposed on the other surface of the printed circuit board,
wherein the first core and the second core comprise a central core penetrating the first hole of the printed circuit board.

20. The transformer according to claim 19, comprising:
a coupling part coupling the first core and the second core.

21. The transformer according to claim 12, comprising:
a bus bar disposed on the pattern coil.
